(19) United States
(12) Patent Application Publication
(10) Pub. No.: US 2022/0103165 A1
(43) Pub. Date: Mar. 31, 2022

(54) FILTERS FOR REMOVING DISTURBANCES FROM SIGNALS

(71) Applicant: ams International AG, Jona (CH)

(72) Inventors: Peter Bliem, Eindhoven (NL); Tero Juhani Niemi, Eindhoven (NL)

(21) Appl. No.: 17/418,093

(22) PCT Filed: Nov. 25, 2019
(86) PCT No.: PCT/EP2019/082474

§ 371 Date: Jun. 24, 2021

Related U.S. Application Data
(60) Provisional application No. 62/785,442, filed on Dec. 27, 2018.

(51) Int. Cl. H03K 5/1252; H03K 19/20

(52) U.S. Cl. CPC H03K 5/1252; H03K 2005/00019; H03K 19/20

(57) ABSTRACT

An example system includes an input terminal operable to receive an input signal having first pulses, a first delay circuit, a second delay circuit, and a latch circuit. The first delay circuit is operable to generate a first delay signal based on the input signal. The first delay signal has second pulses, each including a respective falling edge that is delayed in time with respect to a corresponding falling edge of the first pulses. The second delay circuit is operable to generate a second delay signal based on the input signal. The second delay signal has third pulses, each including a respective falling edge that is delayed in time with respect to a corresponding rising edge of the first pulses. The latch circuit is operable to generate a latch signal based on the first delay signal and based on the second delay signal.

### TECHNICAL FIELD

The disclosure relates to filters for removing disturbances from signals.

### BACKGROUND

A filter can be used to remove or otherwise attenuate components of an electronic signal. As an example, a signal can include one or more primary components (e.g., signal components representing data) and one or more noise components (e.g., one or more signal disturbances that may interfere with the interpretation of the primary component, such as signal spikes or noise). A filter can be used to suppress the noise components partially or completely, while preserving the primary components in the signal.

Example filters include linear or non-linear filters, time-invariant or time-variant filters, causal or not-causal filters, analog or digital filters, discrete-time or continuous-time filters, passive or active filters, and infinite impulse response (IIR) or finite impulse response (FIR) filters, among others.

### SUMMARY

The present disclosure describes filters for removing disturbance from electronic signals. In an example implementation, a filter includes two parallel delay circuits for concurrently processing an input signal, and a latch circuit for generating an output signal based on processed signals from the delay circuits.

The first delay circuit receives the input signal having one or more pulses, and outputs a first delay signal having one or more pulses corresponding to the one or more pulses of the input signal. For each pulse of the first delay signal, the rising edge of the pulse occurs at the same or substantially the same time as the rising edge of the corresponding pulse of the input signal. However, for each pulse of the first delay signal, the falling edge of the pulse is delayed in time with respect to the falling edge of the corresponding pulse of the input signal. Accordingly, the pulses of the first delay signal span a longer interval of time compared to the pulses of the input signal.

The second delay circuit also receives the input signal, and outputs a second delay signal having one or more inverted pulses corresponding to the one or more pulses of the input signal. For each inverted pulse of the second delay signal, the rising edge of the pulse occurs at the same or substantially the same time as the falling edge of the corresponding pulse of the input signal. However, for each inverted pulse of the second delay signal, the falling edge of the pulse is delayed in time with respect to the rising edge of the corresponding pulse of the input signal. Accordingly, the inverted pulses of the second delay signal span a shorter interval of time compared to the pulses of the input signal.

The first and second delay signals are input into a latch circuit (e.g., an S-R latch circuit, such as one implemented using two NAND gates) to produce an output signal. The output signal retains certain types of signal components of the input signal (e.g., signal pulses having pulse durations longer than the time delay introduced by the delay circuits, whereas other types of signal components (e.g., spikes, noise, and signal pulses having pulse durations shorter than the time delay introduced by the delays circuits,) are suppressed. As an example, the output signal can retain signal pulses corresponding to a 1 MHz square wave signal, whereas signal pulses corresponding to a 12.5 MHz square wave signal are suppressed.

Implementations of the filter can provide one or more technical benefits. For example, the filter can be used to preserve useful components of a signal (e.g., signal components representing data being transferred between two or more electronic devices), while suppressing other components of the signal (e.g., one or more signal disturbances that may interfere with the interpretation of the data, such as signal spikes, noise, or pulses having frequencies that are higher than can be interpreted by certain devices). Thus, data can be transmitted between two or more electronic devices in a more accurate manner.

In an aspect, a system includes an input terminal operable to receive an input signal having one or more first pulses, a first delay circuit and a second delay circuit electrically coupled to the input terminal in parallel with one another, and a latch circuit electrically coupled to the first delay circuit and the second delay circuit. The first delay circuit is operable to generate a first delay signal based on the input signal. The first delay signal has one or more second pulses. Each second pulse includes a respective falling edge that is delayed in time with respect to a corresponding falling edge of the one or more first pulses. The second delay circuit is operable to generate a second delay signal based on the input signal. The second delay signal has one or more third pulses. Each third pulse includes a respective falling edge that is delayed in time with respect to a corresponding rising edge of the one or more first pulses. The latch circuit is operable to generate a latch signal based on the first delay signal and based on the second delay signal.

Implementations of this aspect can include one or more of the following features.

In some implementations, the first delay circuit can include a first filter circuit, a first trigger circuit, and a first switch. The first switch can be operable to toggle closed during rising edges of the one or more first pulses of the input signal, and toggle open during falling edges of the one or more first pulses of the input signal.

In some implementations, when the first switch is closed, the first switch can apply a ground voltage to an input of the first trigger circuit. When the second switch is open, a first inverted filtered version of the input signal can be applied to the input of first trigger circuit.

In some implementations, the first trigger circuit can include a Schmitt trigger inverter circuit.

In some implementations, the first trigger circuit can be operable to output, as the first delay signal, a first upper value upon the first switch applying the ground voltage to the input of the first trigger circuit.

In some implementations, the first trigger circuit can be operable to output, as the first delay signal, a first lower value upon the first inverted filtered version of the input signal increasing above a first threshold value.

In some implementations, the second delay circuit can include a second filter circuit, a second trigger circuit, and a second switch. The second switch can be operable to toggle closed during falling edges of the one or more first pulses of the input signal, and toggle open during rising edges of the one or more first pulses of the input signal.

In some implementations, when the second switch is closed, the first switch can apply a rail voltage to an input of the first trigger circuit. When the second switch is open, a second inverted filtered version of the input signal can be applied to the input of second trigger circuit.

In some implementations, the second trigger circuit can include a Schmitt trigger circuit.

In some implementations, the second trigger circuit can be operable to output, as the second delay signal, a second upper value upon the second switch applying the rail voltage to the input of the second trigger circuit.

In some implementations, the second trigger circuit can be operable to output, as the second delay signal, a second lower value upon the second inverted filtered version of the input signal decreasing below a second threshold value.

In some implementations, the latch circuit can include an S-R latch circuit.

In some implementations, the latch circuit can be operable to output, as the latch signal, a third upper value upon the second delay signal decreasing below a third threshold value concurrent to the first delay signal being greater than the third threshold value. The latch circuit can be operable to output, as the latch signal, a third lower value upon the first delay signal decreasing below the third threshold value concurrent to the second delay signal being greater than the third threshold value.

In some implementations, the input signal can include a first signal component and a second signal component, and wherein the latch signal comprises the first signal component without the second signal component.

In some implementations, the first signal component can have a first frequency. The second signal component can have a second frequency higher than the first frequency.

In some implementations, the first frequency can be 1 MHz, and the second frequency can be 12.5 MHz.

In some implementations, the first signal component can include one or more first portions consistent with a first communications protocol, and the second signal component can include one or more second portions consistent with a second communications protocol different from the first communications protocol.

In some implementations, the first communications protocol can be the Inter-Integrated Circuit (I2C) interface standard, and the second communications protocol can be the Mobile Industry Processor Interface (MIPI) I3C interface standard.

In some implementations, the system can include a first electrical component and a second electrical component. The first electrical component can be electrically coupled to the input terminal and can be operable to provide the input signal to the input terminal. The second electrical component can be electrically coupled to the latch circuit and can be operable to receive the latch signal from the latch circuit.

In some implementations, the first electrical component can include a sensor. The input signal can be indicative of a measurement obtained by the sensor.

In some implementations, the first electrical component can include a communications device. The input signal can include a communications signal generated by the communications device.

In some implementations, the second electrical component can be operable to perform one or more signal processing steps based on the latch signal.

In another aspect, a method includes receiving an input signal having one or more first pulses, and generating a first delay signal based on the input signal. The first delay signal has one or more second pulses. Each second pulse includes a respective falling edge that is delayed in time with respect to a corresponding falling edge of the one or more first pulses. The method also includes generating a second delay signal based on the input signal. The second delay signal has one or more third pulses. Each third pulse includes a respective falling edge that delayed in time with respect to a corresponding rising edge of the one or more first pulses. The method also includes generating, by a latch circuit, a latch signal based on the first delay signal and based on the second delay signal.

Implementations of this aspect can include one or more of the following features.

In some implementations, generating the first delay signal can include applying a ground voltage to an input of a first trigger circuit when the input signal is greater than a first switch value, and applying a first inverted filtered version of the input signal to the input of first trigger circuit when the input signal is less than the first switch value.

In some implementations, generating the first delay signal can include outputting, by the first trigger circuit as the first delay signal, a first upper value upon the applying of the ground voltage to the input of the first trigger circuit.

In some implementations, generating the first delay signal can include outputting, by the first trigger circuit as the first delay signal, a first lower value upon the first inverted filtered version of the input signal increasing above a first threshold value.

In some implementations, generating the second delay signal can include applying a rail voltage to an input of a second trigger circuit when the input signal is less than a second switch value, and applying a second inverted filtered version of the input signal to the input of second trigger circuit when the input signal is greater than the second switch value.

In some implementations, generating the second delay signal can include outputting, by the second trigger circuit as the second delay signal, a second upper value upon the applying of the rail voltage to the input of the second trigger circuit.

In some implementations, generating the second delay signal can include outputting, by the second trigger circuit as the second delay signal, a second lower value upon the second inverted filtered version of the input signal decreasing below a second threshold value.

In some implementations, generating the latch signal can include outputting, by the latch circuit as the latch signal, a third upper value upon the second delay signal decreasing below a third threshold value concurrent to the first delay signal being greater than the third threshold value, Further, generating the latch signal can include outputting, by the latch circuit as the latch signal, a third lower value upon the first delay signal decreasing below the third threshold value concurrent to the second delay signal being greater than the third threshold value.

In some implementations, the input signal can include a first signal component and a second signal component. The latch signal can include the first signal component without the second signal component.

In some implementations, the first signal component can have a first frequency. The second signal component can have a second frequency higher than the first frequency.

In some implementations, the first frequency can be 1 MHz, and the second frequency can be 12.5 MHz.

In some implementations, the first signal component can include one or more first portions consistent with a first communications protocol. The second signal component can include one or more second portions consistent with a second communications protocol different from the first communications protocol.

In some implementations, the first communications protocol can be the Inter-Integrated Circuit (I2C) interface standard, and the second communications protocol can be the Mobile Industry Processor Interface (MIPI) I3C interface standard.

In some implementations, the method can further include receiving the input signal from a sensor. The input signal can be indicative of a measurement obtained by the sensor.

In some implementations, the method can further include receiving the input signal from a communications device. The input signal can include a communications signal generated by the communications device.

In some implementations, the method can further include performing one or more signal processing steps based on the latch signal.

In another aspect, a delay circuit includes an input terminal, and an output terminal. The delay circuit is operable to receive an input signal at the input terminal. The input signal has one or more first pulses. The delay circuit is also operable to generate a delay signal based on the input signal. The delay signal has one or more second pulses. Each second pulse includes a respective falling edge that is delayed in time with respect to a corresponding falling edge of the one or more first pulses and a respective rising edge that is concurrent in time with a corresponding rising edge of the one or more first pulses. The delay circuit is also operable to output the delay signal at the output terminal.

In another example, a delay circuits includes an input terminal, and an output terminal. The delay circuit is operable to receive an input signal at the input terminal. The input signal has one or more first pulses. The delay circuit is also operable to generate a delay signal based on the input signal. The delay signal has one or more second pulses. Each second pulse includes a respective falling edge that is delayed in time with respect to a corresponding rising edge of the one or more first pulses and a respective rising edge that is concurrent in time with a corresponding falling edge of the one or more first pulses. The delay circuit is also operable to output the delay signal at the output terminal.

The details of one or more implementations are set forth in the accompanying drawings and the description below. Other features and advantages will be apparent from the description and drawings, and from the claims.

### BRIEF DESCRIPTION OF THE DRAWINGS

FIG. 1 is a schematic diagram of an example electronic system.

FIG. 2 is a schematic diagram of an example filter module.

FIG. 3A-3C show example transient responses of the filter module shown in FIG. 2 during operation.

FIG. 4 is a schematic diagram of another example filter module.

FIG. 5A-5D show example transient responses of the filter module shown in FIG. 4 during operation.

FIG. 6 is a flow chart diagram of an example process for filtering an electronic signal.

FIG. 7A is a schematic diagram of an example rising edge detection circuit.

FIG. 7B is a schematic diagram of an example falling edge detection circuit.

FIG. 8 shows example transient responses of the rising edge detection circuit shown in FIG. 7A and the falling edge detection circuit shown in FIG. 7B during operation.

### DETAILED DESCRIPTION

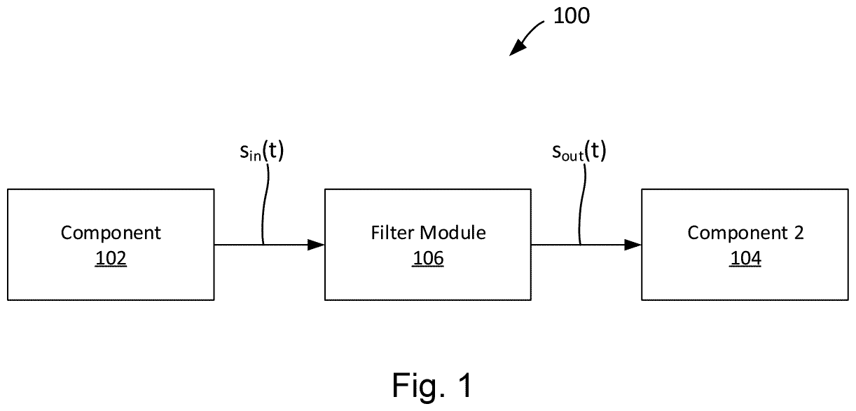

FIG. 1 is a schematic diagram of an example electronic system 100. The electronic system 100 includes a first electronic component 102, a second electronic component 104, and a filter module 106. In an example usage of the electronic system 100, the first component 102 generates an electronic input signal sᵢₙ(t), and transmits the input signal sᵢₙ(t) to the filter module 106. The filter module 106 filters the input signal sᵢₙ(t) (e.g., preserves certain useful components of the signal, such as components representing data, while suppressing other components of the signal, such as noise), and outputs a filtered electronic signal sₒᵤₜ(t) to the component 104.

The components 102 and 104 can be any electronic components that transmit and/or receive data. As an example, the components 102 and/or 104 can be a sensor module (e.g., a component that obtains measurements of an environment, and generates sensor signals indicative of the measurements), a communications device (e.g., a component that generates communications signals indicative of electronic messages or other information), or other types of electronic devices.

In some cases, the input signal sᵢₙ(t) includes one or more pulses (e.g., one or more variations in signal amplitude, such as rectangular pulses, cosine squared pulses, Dirac pulses, sinc pulses, Gaussian pulses, or pulse having other shapes). The filter module 106 can filter the input signal sᵢₙ(t) such that the output signal output signal sₒᵤₜ(t) retains certain pulses from the input signal sᵢₙ(t) (e.g., pulses having a particular frequency or range of frequencies), whereas other types of signal components (e.g., spikes, noise, and pulses having another frequency or range of frequencies, such as 12.5 MHz) are suppressed.

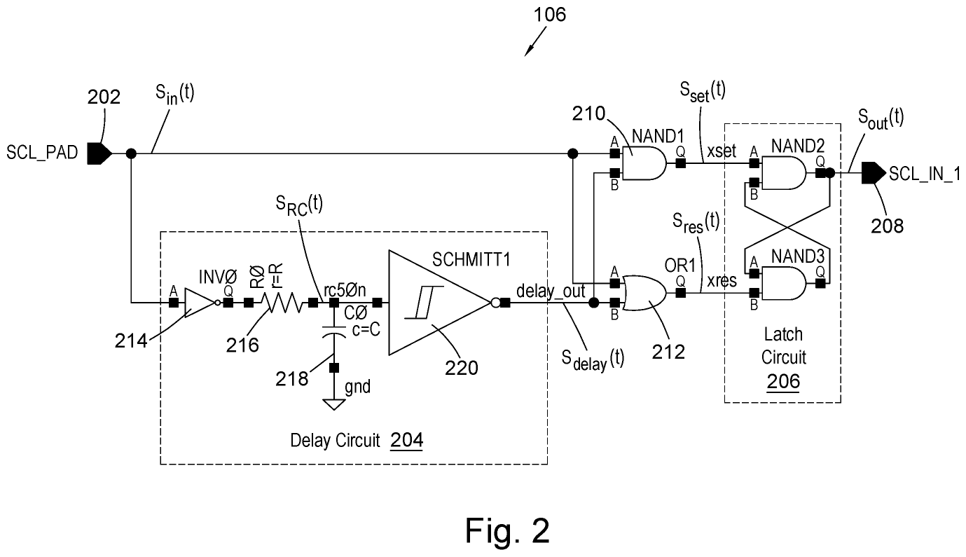

FIG. 2 shows an example filter module 106. The filter module 106 includes an input terminal 202, a delay circuit 204, a latch circuit 206, and an output terminal 208. In an example usage of the filter module 106, the filter module 106 receives an input signal sᵢₙ(t) at the input terminal 202. The delay circuit 204 generates a delayed version of the input signal s_{delay} (t). A latch set signal sₛₑₜ (t) is generated based on the input signal sᵢₙ(t) and the delayed signal s_{delay}(t) using a NAND gate 210. Further, a latch reset signal sᵣₑₛ (t) is generated based on the input signal sᵢₙ(t) and the delayed signal s_{delay} (t) using an OR gate 212. The latch reset signal sᵣₑₛ (t) and the latch set signal sₛₑₜ (t) are input into the latch circuit 206 (e.g., an S-R latch circuit, such as one implemented using two NAND gates) to produce the output signal sₒᵤₜ(t). The output signal sₒᵤₜ(t) is output at the output terminal 208.

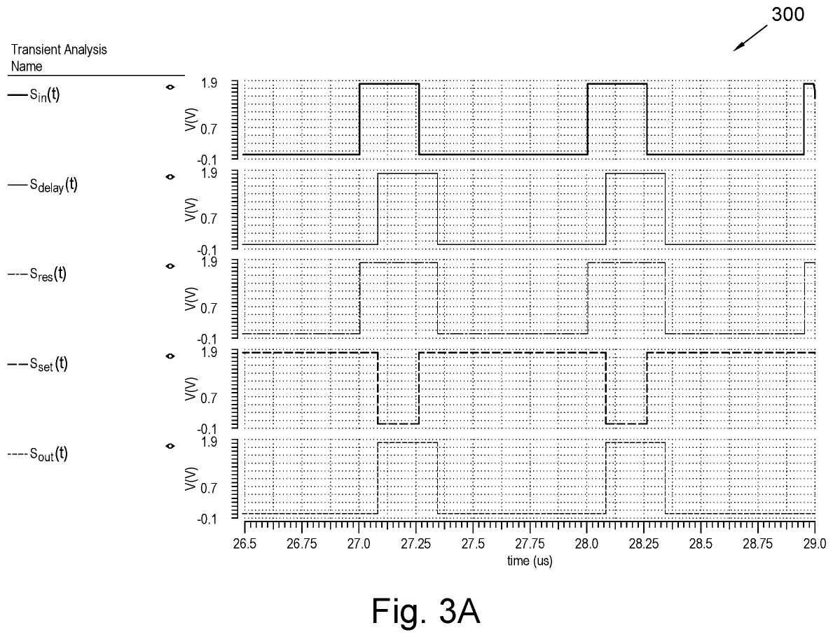

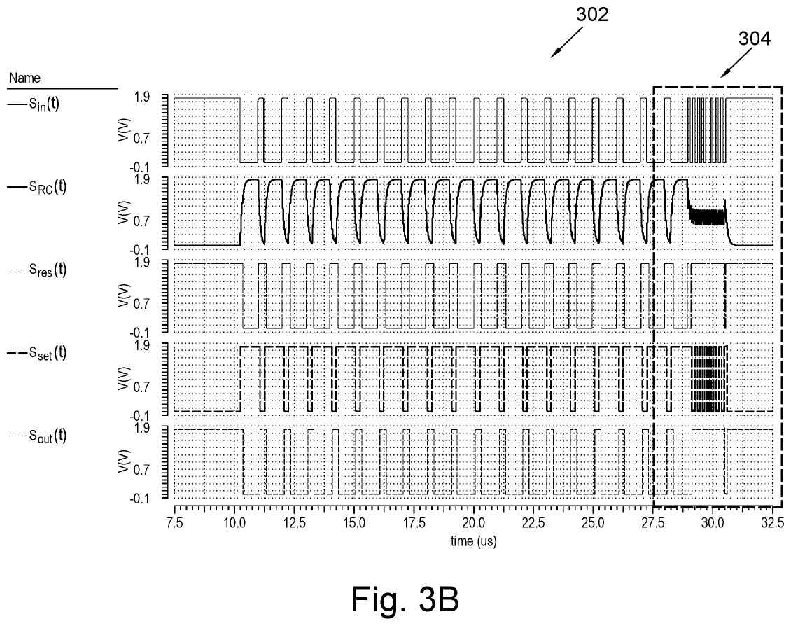

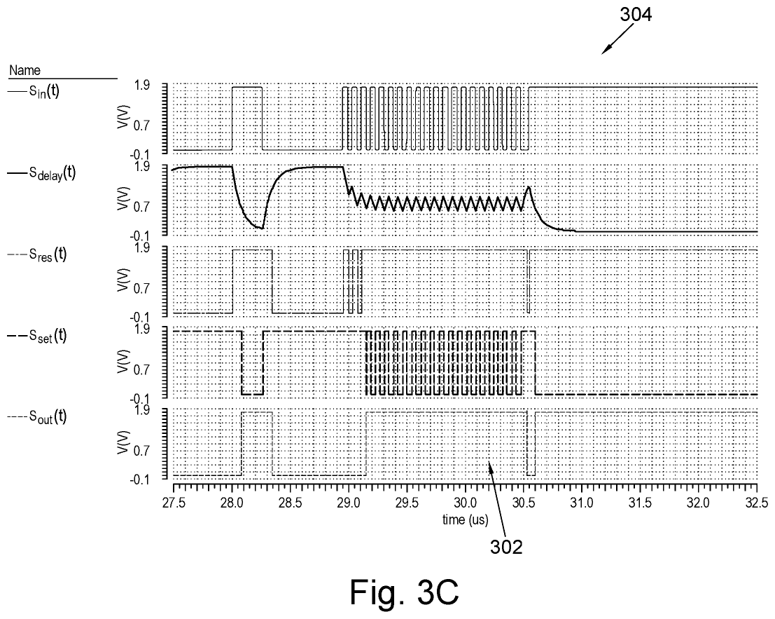

FIG. 3A shows example transient responses 300 of the filter module 106 during operation.

As shown in FIG. 3A, the delayed signal s_{delay}(t) is a delayed version of the input signal sᵢₙ(t) is delayed in time with respect to the input signal sᵢₙ(t). As shown in FIG. 2, the delay circuit 204 includes an inverter 214, a resistor 216 and capacitor 218 forming an RC filter, and a Schmitt trigger inverter 220. When the input signal sᵢₙ(t) is applied to the delay circuit 204, the input signal sᵢₙ(t) is inverted by the inverter 214, and is filtered according to the RC filter (e.g., smoothed according to an RC time constant) to produce an RC filtered signal s_{RC} (t). The RC filtered signal s_{RC} (t) is input into the Schmitt trigger inverter 220, which produces the delayed signal s_{delay}(t). The Schmitt trigger inverter 220 is a trigger circuit with hysteresis that (i) outputs a signal toggling from a low voltage amplitude to a high voltage amplitude when an amplitude of an input signal decreases from above a threshold trigger value to below the threshold trigger value, and (ii) outputs a signal toggling from a high voltage amplitude to a low voltage amplitude when the amplitude of the input signal increases from below the threshold trigger value to above the threshold trigger value.

As shown in FIG. 3A the delayed signal s_{delay}(t) includes a number of pulses, each corresponding to a different respective pulse in the input signal sᵢₙₚᵤₜ (t). However, each of the pulses of the delayed signal s_{delay}(t) is delayed in time with respect to its corresponding pulses of the input signal sᵢₙₚᵤₜ (t). This delay is caused by the RC filter and the Schmitt trigger inverter 220. For example, the voltage across the capacitor as a function of time during discharge can be defined as:

$${V}_{c} = {V}_{supply} {e}^{- \frac{t}{RC}} ,$$

where V_{c} is the voltage across the capacitor 218, V_{supply} is the supply voltage, t is the elapsed time since the start of the discharge of the capacitor 218, and RC is the tiem constant. If the Schmitt trigger is designed so that the output is changing the state when the input is in the middle of the supply range, using the above relationship, the RC time constant approximately equals to 0.7RC:

t=−LN(V_{c}/V_{supply}*RC=−ln(0.5)*RC=0.69*RC

Accordingly, the RC values together with the Schmitt trigger threshold control the delay.

As shown in the example of FIG. 3A, the latch reset signal sᵣₑₛ (t) is an OR-function of the input signal sᵢₙ(t) and the delayed signal s_{delay} (t) output by the delay circuit 204. When either of the input signal sᵢₙ(t) and the delayed signal s_{delay}(t) has a high voltage amplitude (e.g., a rail voltage of the system), the latch reset signal sᵣₑₛ(t) also has a high voltage amplitude. When neither the input signal sᵢₙ(t) nor the delayed signal s_{delay}(t) has a high voltage amplitude, the latch reset signal sᵣₑₛ(t) has a low voltage amplitude (e.g., ground).

As further shown in FIG. 3A, the latch set signal sₛₑₜ (t) is an NAND-function of the input signal sᵢₙ(t) and the delayed signal s_{delay} (t) output by the delay circuit 204. When both the input signal sᵢₙ(t) and the delayed signal s_{delay}(t) have a high voltage amplitude (e.g., a rail voltage of the system), the latch set signal sᵣₑₛ(t) has a low voltage amplitude. Otherwise, the latch set sₛₑₜ(t) has a high voltage amplitude (e.g., ground).

As shown in FIG. 3A, the output signal sₒᵤₜ(t) is generated based on the latch reset signal sᵣₑₛ(t) and the latch set signal sₛₑₜ (t). When the latch set signal sₛₑₜ (t) decreases from a high voltage amplitude to a low voltage amplitude concurrent to the latch reset signal sᵣₑₛ(t) having a high voltage amplitude, the output signal sₒᵤₜ(t) transitions from a low voltage amplitude to a high voltage amplitude. When the latch reset signal sᵣₑₛ(t) decreases from a high voltage amplitude to a low voltage amplitude concurrent to the latch set signal sₛₑₜ (t) having a high voltage amplitude, the output signal sₒᵤₜ(t) transitions from a high voltage amplitude to a low voltage amplitude.

The output signal sₒᵤₜ(t) represents a filtered and delayed version of the input signal sᵢₙ(t). For instance, transient disturbances in the input signal sᵢₙ(t) (e.g., signal pulses having pulse durations shorter than the time delay introduced by the delays circuits, such as signal spikes, noise, or other spurious signal components) are removed or otherwise attenuated due the filtering by the RC filter in generating the delayed signal s_{delay}(t). In practice, the RC filter can be tuned (e.g., by selecting appropriate resistance and capacitance values for the resistor 216 and the capacitor 218) to adjust its filtering response and its delaying effect on the output signal sₒᵤₜ(t). Further, each pulse of the input signal sᵢₙ(t) is sharpened due to the trigger output of the Schmitt trigger inverter 220 in generating the delayed signal s_{delay}(t). Accordingly, the output signal sₒᵤₜ(t) may be interpreted more accurately by the receiving electronic component (e.g., compared to the input signal sᵢₙ(t)).

In some cases, the filter module 106 may be less suitable for filtering out certain high frequency signal components (e.g., high frequency pulses) from the input signal sᵢₙ(t). As an example, FIG. 3B shows example transient responses 302 of the filter module 106 during operation. In this example, the input signal sᵢₙ(t) includes a sequence of lower frequency pulses (e.g., 1 MHz pulses) that should be retained in the output signal sₒᵤₜ(t) followed by a sequence of higher frequency pulses (e.g., 12.5 MHz pulses) that should be removed from the output signal sₒᵤₜ(t). During the sequence of lower frequency pulses, the RC filtered signal s_{RC}(t) increases and decays fully according to the RC time constant. Accordingly, the filter module generates an output signal sₒᵤₜ (t) that represents a filtered and delayed version of the input signal sᵢₙ(t).

However, during the sequence of higher frequency pulses, the RC filtered signal s_{RC} (t) does not have sufficient time to increase or decay fully according to the RC time constant, and instead exhibits a DC shift (e.g., an intermediate value between the lower voltage amplitude and the high voltage amplitude). This can cause unintended toggling of the delayed signal s_{delay}(t) (e.g., due to unintended triggering of the Schmitt trigger inverter 220), and can result in an anomalous output signal sₒᵤₜ(t) (e.g., an output signal that no longer represents a filtered and delayed version of the input signal sᵢₙ(t)) due to toggling of the latch circuit 206.

To illustrate, the portion 304 of the transient responses 302 is shown in greater detail in FIG. 3C. As shown in FIG. 3C, after a few high frequency pulses in the input signal sᵢₙ(t), the filter module generates a output signal sₒᵤₜ(t) having a lengthy high voltage amplitude pulse 302 that is not filtered away. Accordingly, electronic components receiving the output signal sₒᵤₜ(t) may interpret the signal incorrectly.

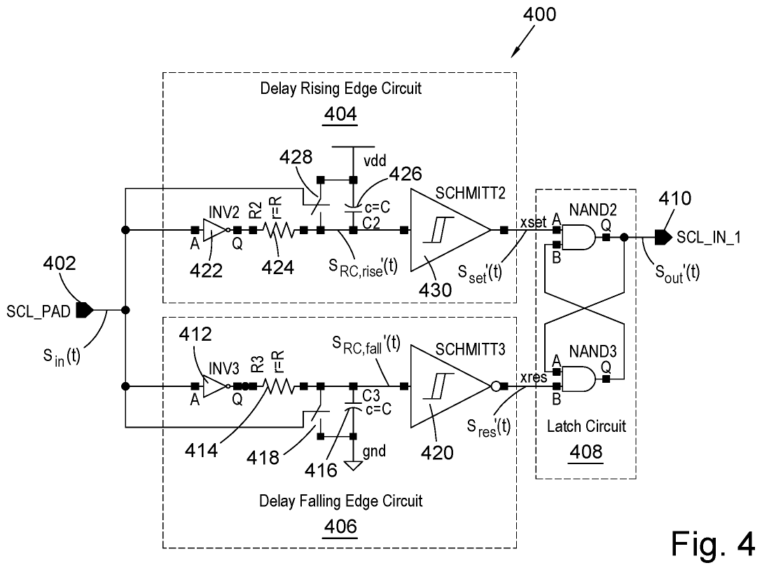

FIG. 4 shows another example filter module 400. In some cases, the filter module 400 can be used to preserve certain types of signal components of an input signal (e.g., signal pulses having a particular frequency or range of frequencies, such as 1 MHz), while suppressing other types of signal components (e.g., signal pulses having another frequency or range of frequencies, such as 12.5 MHz). In some cases, the filter module 400 can be used to filter signals that are transmitted between two electrical components (e.g., as shown in FIG. 1).

The filter module 400 includes an input terminal 402, a delay rising edge circuit 404 and a delay falling edge circuit 406 electrically coupled to the input terminal 402 in parallel, a latch circuit 408 electrically coupled to the outputs of the delay rising edge circuit 404 and the delay falling edge circuit 406, and an output terminal 410 electrically coupled to an output of the latch circuit 408.

In an example usage of the filter module 400, the filter module 400 receives an input signal sᵢₙ(t) at the input terminal 402. The delay falling edge circuit 406 receives the input signal sᵢₙ(t) from the input terminal 402, and outputs a latch reset signal sᵣₑₛ (t) having one or more pulses (e.g., periods of high voltage, such as a rail voltage) corresponding to one or more pulses of the input signal sᵢₙ(t). For each pulse of the latch reset signal sᵣₑₛ′(t), the rising edge of the pulse (e.g., the transition from a low voltage, such as ground, to a high voltage, such as a rail voltage) occurs at the same or substantially the same time as the rising edge of the corresponding pulse of the input signal sᵢₙ(t). However, for each pulse of the latch reset signal sᵣₑₛ′(t), the falling edge of the pulse (e.g., the transition from a high voltage to a low voltage) is delayed in time with respect to the falling edge of the corresponding pulse of the input signal sᵢₙ(t). Accordingly, the pulses of the latch reset signal sᵣₑₛ′(t) span a longer interval of time compared to the pulses of the input signal sᵢₙ(t).

The delay rising edge circuit 404 also receives the input signal sᵢₙ(t), and outputs a latch set signal sₛₑₜ′(t) having one or more inverted pulses (e.g., periods of low voltage, such ground) corresponding to the one or more pulses of the input signal sᵢₙ(t). For each inverted pulse of the latch set signal sₛₑₜ′(t), the rising edge of the pulse occurs at the same or substantially the same time as the falling edge of the corresponding pulse of the input signal sᵢₙ(t). However, for each inverted pulse of the latch set signal sₛₑₜ′(t), the falling edge of the pulse is delayed in time with respect to the rising edge of the corresponding pulse of the input signal sᵢₙ(t). Accordingly, the inverted pulses of the latch set signal sₛₑₜ′(t) span a shorter interval of time compared to the pulses of the input signal sᵢₙ(t).

The latch reset signal sᵣₑₛ′(t) and the latch reset signal sᵣₑₛ′(t) are input into the latch circuit 408 (e.g., an S-R latch circuit, such as one implemented using two NAND gates) to produce an output signal sₒᵤₜ′(t), which is output from the output terminal 410. The output signal sₒᵤₜ′(t) retains certain types of signal components of the input signal sᵢₙ(t) (e.g., signal pulses having pulse durations longer than the time delay introduced by the delay circuits), whereas other types of signal components (e.g., spikes, noise, and signal pulses having pulse durations shorter than the time delay introduced by the delays circuits) are suppressed. As an example, the output signal can retain signal pulses corresponding to a 1 MHz square wave signal, whereas signal pulses corresponding to a 12.5 MHz square wave signal are suppressed.

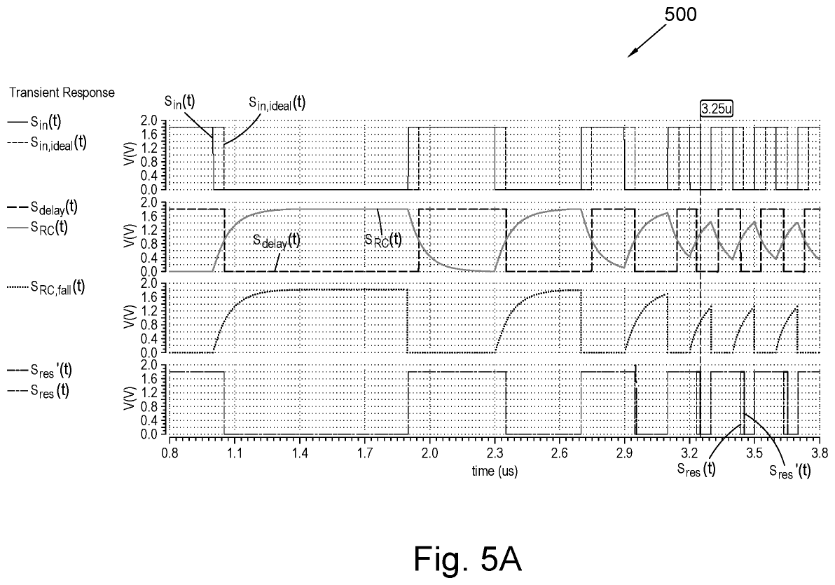

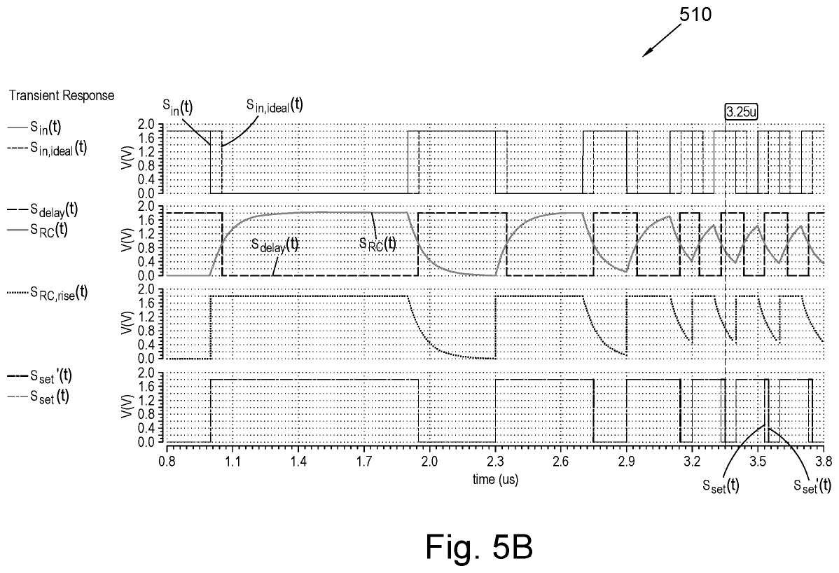

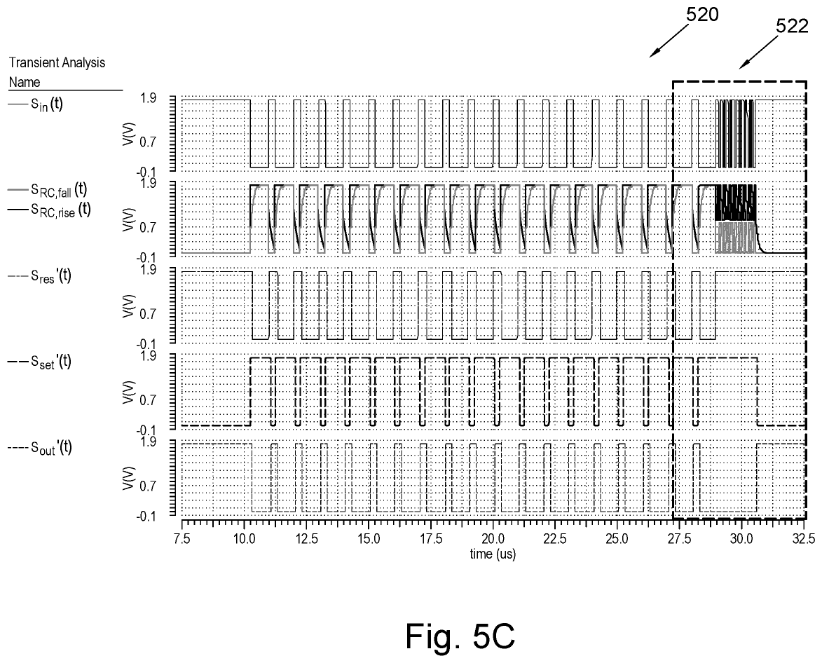

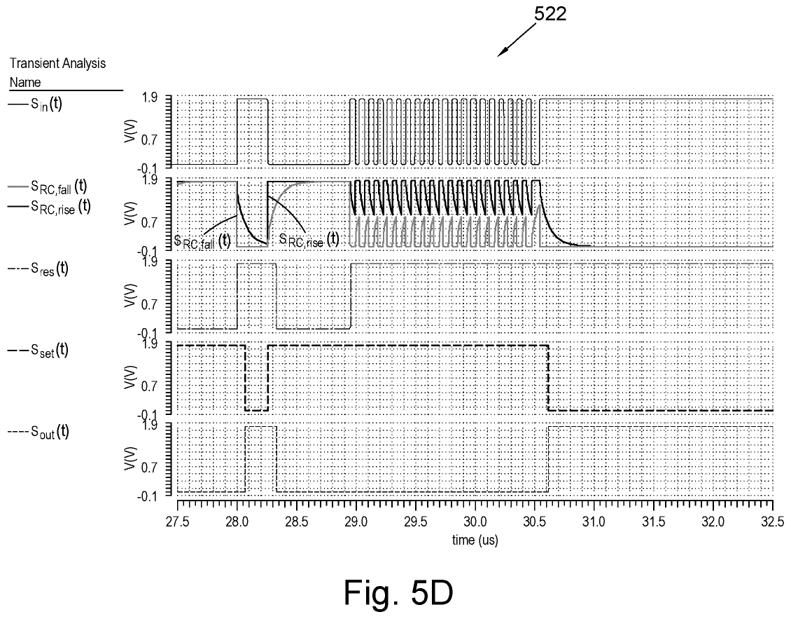

FIG. 5A shows example transient responses 500 of the filter modules 106 and 400 during operation. In this example, an input signal sᵢₙ(t) having pulse widths of 800 ns, 400 ns, 200 ns, and 100 ns is applied to the filter modules 106 and 400 having a delay of 50 ns, and the resulting latch reset signals sᵣₑₛ (t) and sᵣₑₛ′(t) of the filter modules 106 and 400, respectively, are measured.

As shown in FIG. 4, the delay falling edge circuit 406 includes an inverter 412, a resistor 414 and a capacitor 416 forming an RC filter, a switch 418 (e.g., an n-type switch), and a Schmitt trigger inverter 420. When the input signal sᵢₙ(t) is applied to the delay falling edge circuit 406, the input signal sᵢₙ(t) is also applied to a control gate of the switch 418. When the input signal sᵢₙ(t) transitions from a low voltage amplitude (e.g., ground) to a high voltage amplitude (e.g., rail voltage), the switch 418 closes (e.g., upon the voltage amplitude crossing a switch value of the switch 418). Upon closing of the switch 418, ground voltage is applied to the input of the Schmitt trigger inverter 420.

The Schmitt trigger inverter 420 is a trigger circuit with hysteresis that (i) outputs a signal toggling from a low voltage amplitude to a high voltage amplitude when an amplitude of an input signal decreases from above a threshold trigger value to below the threshold trigger value, and (ii) outputs a signal toggling from a high voltage amplitude to a low voltage amplitude when the amplitude of the input signal increases from below the threshold trigger value to above the threshold trigger value. Accordingly, upon closing of the switch 418, the Schmitt trigger inverter 420 outputs a latch reset signal sᵣₑₛ′(t) that toggles from a low voltage amplitude to a high voltage amplitude (e.g., forming a pulse having a rising edge occurring at the same or substantially the same time as the rising edge of the pulse of the input signal sᵢₙ(t)).

When the input signal sᵢₙ(t) transitions from a high voltage amplitude to a low voltage amplitude, the switch 418 opens (e.g., upon the voltage amplitude crossing the switch value of the switch 418). Upon opening of the switch 418, the input signal sᵢₙ(t) is inverted by the inverter 412, and is filtered according to the RC filter formed by the resistor 414 and capacitor 416 (e.g., smoothed according to an RC time constant) to produce an RC filtered signal s_{RC,fall} (t). The RC filtered signal s_{RC,fall} (t) is input into the Schmitt trigger inverter 420. The Schmitt trigger inverter 420 outputs a latch reset signal sᵣₑₛ′(t) that toggles from a high voltage amplitude to a low voltage amplitude when the RC filtered signal s_{RC,fall} (t) increases above the threshold trigger value (e.g., forming a pulse having a falling edge that is delayed in time with respect to the falling edge of the pulse of the input signal sᵢₙ(t)).

As shown in FIG. 5A, the latch reset signal sᵣₑₛ′(t) generated by the delay falling edge circuit 406 represents a filtered and delayed version of the input signal sᵢₙ(t) across each of the different pulses widths, and more closely matches the falling edge of an “ideal” delayed input signal s_{in,ideal} (t) (e.g., a perfectly time-shifted version of the input signal sᵢₙ(t)) and the rising edge of the input signal sᵢₙ(t). In contrast, the latch reset signal sᵣₑₛ (t) generated by the filter module 106 includes pulses that deviate to a greater extent in width compared to the pulses of the input signal sᵢₙ(t) (e.g., in response to the narrower pulses on the right side of the plots).

FIG. 5B shows additional example transient responses 510 of the filter modules 106 and 400 during operation. In this example, an input signal sᵢₙ(t) having pulse widths of 800 ns, 400 ns, 200 ns, and 100 ns is applied to the filter modules 106 and 400 having a delay of 50 ns, and the resulting latch set signals sₛₑₜ (t) and sₛₑₜ′(t) of the filter modules 106 and 400, respectively, are measured.

As further shown in FIG. 4, the delay rising edge circuit 404 includes an inverter 422, a resistor 424 and a capacitor 426 forming an RC filter, a switch 428 (e.g., a p-type switch), and a Schmitt trigger 430. When the input signal sᵢₙ(t) is applied to the delay rising edge circuit 404, the input signal sᵢₙ(t) is also applied to a control gate of the switch 428. When the input signal sᵢₙ(t) transitions from a high voltage amplitude (e.g., rail voltage) to a low voltage amplitude (e.g., ground), the switch 428 closes (e.g., upon the voltage amplitude crossing a switch value of the switch 418). Upon closing of the switch 428, rail voltage is applied to the input of the Schmitt trigger 430.

The Schmitt trigger 430 is a trigger circuit with hysteresis that (i) outputs a signal toggling from a low voltage amplitude to a high voltage amplitude when an amplitude of an input signal increases from below a threshold trigger value to above the threshold trigger value, and (ii) outputs a signal toggling from a high voltage amplitude to a low voltage amplitude when the amplitude of the input signal decreases from above the threshold trigger value to below the threshold trigger value. Accordingly, upon closing of the switch 428, the Schmitt trigger 430 outputs a latch set signal sₛₑₜ′(t) that toggles from a low voltage amplitude to a high voltage amplitude (e.g., forming an inverted pulse having a rising edge occurring at the same or substantially the same time as the falling edge of the pulse of the input signal sᵢₙ(t)).

When the input signal sᵢₙ(t) transitions from a low voltage amplitude to a high voltage amplitude, the switch 428 opens (e.g., upon the voltage amplitude crossing the switch value of the switch 428). Upon opening of the switch 428, the input signal sᵢₙ(t) is inverted by the inverter 422, and is filtered according to the RC filter formed by the resistor 424 and capacitor 426 (e.g., smoothed according to an RC time constant) to produce an RC filtered signal s_{RC,rise}(t). The RC filtered signal s_{RC,rise} (t) is input into the Schmitt trigger 430. The Schmitt trigger 430 outputs a latch set signal sₛₑₜ′(t) that toggles from a high voltage amplitude to a low voltage amplitude when the RC filtered signal s_{RC,rise}(t) decreases below the threshold trigger value (e.g., forming an inverted pulse having a falling edge that is delayed in time with respect to the rising edge of the pulse of the input signal sᵢₙ(t).

As shown in FIG. 5B, the latch set signal sₛₑₜ′(t) generated by the delay rising edge circuit 404 represents an inverted, filtered, and delayed version of the input signal sᵢₙ(t) across each of the different pulses widths, and more closely matches the rising edge of an inverted version of an “ideal” delayed input signal s_{in,ideal} (t) (e.g., a perfectly time-shifted version of the input signal sᵢₙ(t)) and the falling edge of the input signal sᵢₙ(t). In contrast, the latch set signal sₛₑₜ(t) generated by the filter module 106 includes inverted pulses that deviate to a greater extent in width compared to the pulses of the input signal sᵢₙ(t) (e.g., in response to the narrower pulses on the right side of the plots).

The latch reset signal sᵣₑₛ′(t) generated by the delay falling edge circuit 406 and the latch set signal sₛₑₜ′(t) generated by the delay rising edge circuit 404 are input into the latch circuit 408 (e.g., an S-R latch, such as one implemented using two NAND gates). The latch circuit 408 can function in a manner similar to the latch circuit 206 described with respect to FIG. 2.

For example, FIG. 5C shows example transient responses 520 of the filter module 400 during operation. As shown in FIG. 5C, when the latch set signal sₛₑₜ′(t) decreases from a high voltage amplitude to a low voltage amplitude concurrent to the latch reset signal sᵣₑₛ′(t) having a high voltage amplitude, the output signal sₒᵤₜ′(t) transitions from a low voltage amplitude to a high voltage amplitude. When the latch reset signal sᵣₑₛ′(t) decreases from a high voltage amplitude to a low voltage amplitude concurrent to the latch set signal sₛₑₜ′(t) having a high voltage amplitude, the output signal sₒᵤₜ′(t) transitions from a high voltage amplitude to a low voltage amplitude.

The output signal sₒᵤₜ′(t) represents a filtered and delayed version of the input signal sᵢₙ(t). For instance, transient disturbances in the input signal sᵢₙ(t) (e.g., signal spikes, noise, and signal pulses having pulse durations shorter than the time delay introduced by the delays circuits) are removed or otherwise attenuated due the filtering by the RC filters in generating the latch reset signal sᵣₑₛ′(t) and the latch set signal sₛₑₜ′(t). In practice, the RC filters can be tuned (e.g., by selecting appropriate resistance and capacitance values for the resistors 414 and 424 and the capacitors 416 and 426) to adjust their filtering responses and their delaying effect on the latch reset signal sᵣₑₛ′(t), the latch set signal sₛₑₜ′(t), and the output signal sₒᵤₜ(t). Further, each pulse of the input signal sᵢₙ(t) is sharpened due the trigger outputs of the Schmitt trigger inverter 420 and the Schmitt trigger 430 in generating the latch reset signal sᵣₑₛ′(t) and the latch set signal sₛₑₜ′(t). Accordingly, the output signal sₒᵤₜ′(t) may be interpreted more accurately by the receiving electronic component (e.g., compared to the input signal sᵢₙ(t)).

Further, the filter module 400 may be particularly suitable for filtering out certain high frequency signal components (e.g., high frequency pulses) from the input signal sᵢₙ(t). For instance, in the example shown in FIG. 5C, the input signal sᵢₙ(t) includes a sequence of lower frequency pulses (e.g., 1 MHz pulses) that should be retained in the output signal sₒᵤₜ(t), followed by a sequence of higher frequency pulses (e.g., 12.5 MHz pulses) that should be removed from the output signal sₒᵤₜ′(t). During the sequence of lower frequency pulses, each of the RC filtered signals s_{RC,rise}(t) and s_{RC,fall} (t) increases and decays fully according to its respective RC time constant. Accordingly, the filter module generates an output signal sₒᵤₜ′(t) that represents a filtered and delayed version of the input signal sᵢₙ(t).

Further, during the sequence of higher frequency pulses, the RC filtered signals s_{RC,rise} (t) and s_{RC,fall}(t) have time to either increase or decay fully according to the RC time constant, without exhibiting a DC shift. Accordingly, the effects of the high frequency pulses are filtered out, and do not induce a change in the latch set signal sₛₑₜ′(t) or the latch reset signal sᵣₑₛ′(t). Thus, the high frequency pulses are filtered out of the resulting output signal sₒᵤₜ′(t).

To illustrate, the portion 522 of the transient responses 520 are shown in greater detail in FIG. 5D. As shown in FIG. 5D, although the input signal sᵢₙ(t) includes several high frequency pulses in a sequence, the filter module generates an output signal sₒᵤₜ′(t) with those high frequency pulses removed, while preserving the low frequency pulses.

The filter module 400 can be used in various contexts. For example, the filter module 400 can be used to preserve useful components of a signal (e.g., signal components representing data being transferred between two or more electronic devices), while suppressing other components of the signal (e.g., one or more signal disturbances that may interfere with the interpretation of the data, such as signal spikes, noise, or pulses having frequencies that are higher than can be interpreted by certain devices). Thus, data can be transmitted between two or more electronic devices in a more accurate manner.

In some cases, the filter module 400 can be used to preserve signal components corresponding to a first communications protocol in a signal, while removing signal components corresponding to a second communications protocol from the signal. For example, the filter module 400 can be used to preserve signal components corresponding to the Inter-Integrated Circuit (I2C) interface standard (e.g., 1 MHz pulses), while removing signal components corresponding to the Mobile Industry Processor Interface (MIPI) I3C interface standard (e.g., 12 MHz pulses). This can be useful, for example, in improving the compatibility between different electronic devices (e.g., by removing signal components that a receiving device cannot interpret, while retaining signal components that the receiving device can interpret).

In some cases, the filter module can be used to filter the output of a sensor module, and provide the filtered output to another electronic device for further processing and/or storage (e.g., a computer processor, a storage device, etc.). In some cases, the filter module can be used to filter the output for a communications module (e.g., a radio transceiver), and provide the filtered output to another electric device for interpretation.

### Example Processes

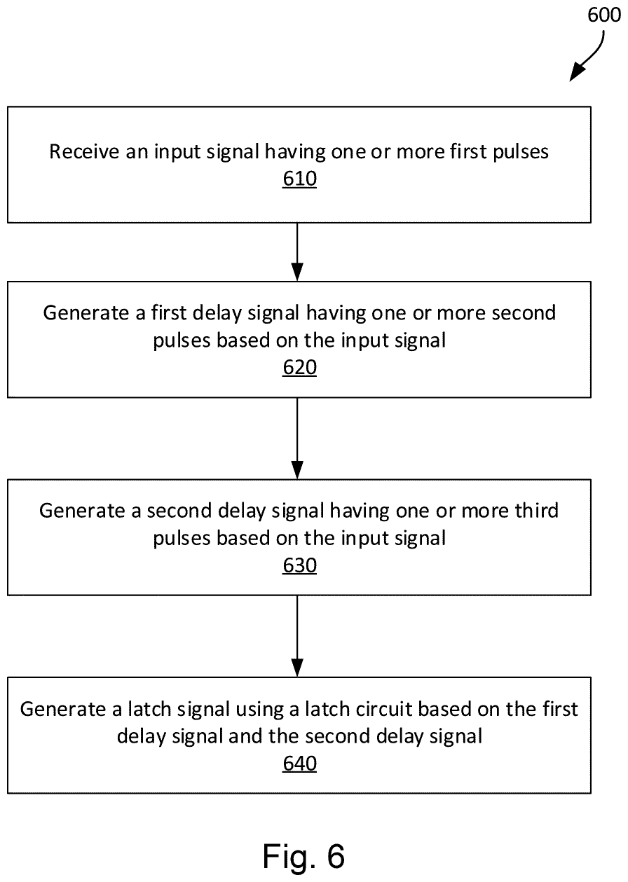

An example process 600 for filtering an electronic signal is show in FIG. 6. In some cases, the process 600 can be performed by the system 100 and the filter module 106 shown in FIGS. 1 and 4.

In the process 600, an input signal having one or more first pulses is received (step 610). As an example, an input signal sᵢₙ(t) can be received by the input terminal 412 of the filter module 400.

A first delay signal is generated based on the input signal (step 620). The first delay signal has one or more second pulses. Each second pulse includes a respective falling edge that is delayed in time with respect to a corresponding falling edge of the one or more first pulses. As an example, a latch reset signal sᵣₑₛ′(t) can be generated by the delay falling edge circuit 406 of the filter module 400.

Techniques for generating the first delay signal are described herein (e.g., with respect to FIGS. 4 and 5A-5D). For example, generating the first delay signal can include applying a ground voltage to an input of a first trigger circuit when the input signal is greater than a first switch value, and applying a first inverted filtered version of the input signal to the input of first trigger circuit when the input signal is less than the first switch value. The first trigger circuit can output, as the first delay signal, a first upper value upon the applying of the ground voltage to the input of the first trigger circuit. The first trigger circuit can output, as the first delay signal, a first lower value upon the first inverted filtered version of the input signal increasing above a first threshold value.

A second delay signal is generated based on the input signal (step 630). The second delay signal has one or more third pulses. Each third pulse includes a respective falling edge that delayed in time with respect to a corresponding rising edge of the one or more first pulses. As an example, a latch set signal s′ₛₑₜ (t) can be generated by the delay rising edge circuit 404 of the filter module 400.

Techniques for generating the second delay signal are described herein (e.g., with respect to FIGS. 4 and 5A-5D). For example, generating the second delay signal can include applying a rail voltage to an input of a second trigger circuit when the input signal is less than a second switch value, and applying a second inverted filtered version of the input signal to the input of second trigger circuit when the input signal is greater than the second switch value. The second trigger circuit can output, as the second delay signal, a second upper value upon the applying of the rail voltage to the input of the second trigger circuit. The second trigger circuit can output, as the second delay signal, a second lower value upon the second inverted filtered version of the input signal decreasing below a second threshold value.

A latch signal is generated by a latch circuit based on the first delay signal and based on the second delay signal (step 640). As an example, a latch signal sₒᵤₜ(t) can be generated using the latch circuit 408 of the filter module 400 (e.g., an S-R latch, such as one implemented using two NAND gates). Generating the latch signal can include outputting, by the latch circuit as the latch signal, a third upper value upon the second delay signal decreasing below a third threshold value concurrent to the first delay signal being greater than the third threshold value. Generating the latch signal can include outputting, by the latch circuit as the latch signal, a third lower value upon the first delay signal decreasing below the third threshold value concurrent to the second delay signal being greater than the third threshold value.

In some cases, the input signal can include a first signal component and a second signal component. The latch signal can include the first signal component without the second signal component. For instance, the first signal component can have a first frequency, and the second signal component can have a second frequency higher than the first frequency. As an example, the first frequency can be 1 MHz (e.g., corresponding to 1 MHz signal pulses), and wherein the second frequency is 12.5 MHz (e.g., corresponding to 12.5 MHz signal pulses).

In some cases, the first signal component can include one or more first portions consistent with a first communications protocol, and the second signal component can include one or more second portions consistent with a second communications protocol different from the first communications protocol. As an example, the first communications protocol can be the Inter-Integrated Circuit (I2C) interface standard, and the second communications protocol can be the Mobile Industry Processor Interface (MIPI) I3C interface standard.

In some cases, the input signal can be received from a sensor. The input signal can be indicative of a measurement obtained by the sensor (e.g., a sensor signal).

In some cases, the input signal can be received from a communications device. The input signal can include a communications signal generated by the communications device.

In some cases, one or more signal processing steps can be performed based on the latch signal. For example, the latch signal can be interpreted and/or stored by a computer system or other device.

In the example filter module 400 shown in FIG. 4, a delay rising edge circuit 404 and a delay falling edge circuit 406 are used in conjunction to generate input signals for a latch circuit 408 (e.g., to filter certain components of an input signal sᵢₙ(t) from an output signal sₒᵤₜ(t)). However, the delay rising edge circuit 404 and/or the delay falling edge circuit 406 also can be used for other purposes.

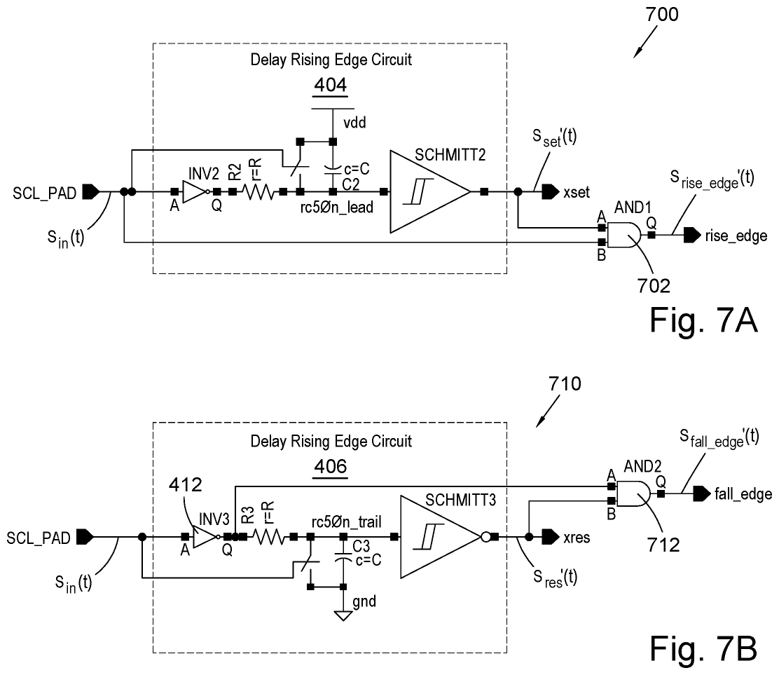

As an example, FIG. 7A shows a rising edge detection circuit 700 including a delay rising edge circuit 404. The rising edge detection circuit 700 can be used to detect rising edges of an input signal sᵢₙ(t) (e.g., portions of the input signal sᵢₙ(t) that transition from a low voltage, such as ground, to a high voltage, such as a rail voltage), and generate a signal pulse upon the occurrence of the rising edge. The delay rising edge circuit 404 can be similar to the delay rising edge circuit 404 shown and described with respect to FIG. 4.

In an example operation of the rising edge detection circuit 700, the output of the delay rising edge circuit 404 (i.e., latch set signal sₛₑₜ′(t)) is input into an AND gate 702. Further, the input signal sᵢₙ(t) is also input into the AND gate 702. When both the latch set signal sₛₑₜ′(t) and the input signal sᵢₙ(t) are at a high voltage, the AND gate 702 outputs a high voltage as a rising edge detection signal s_{rise_edge}(t). Otherwise, the AND gate 702 outputs a low voltage as the rising edge detection signal s_{rise_edge}(t).

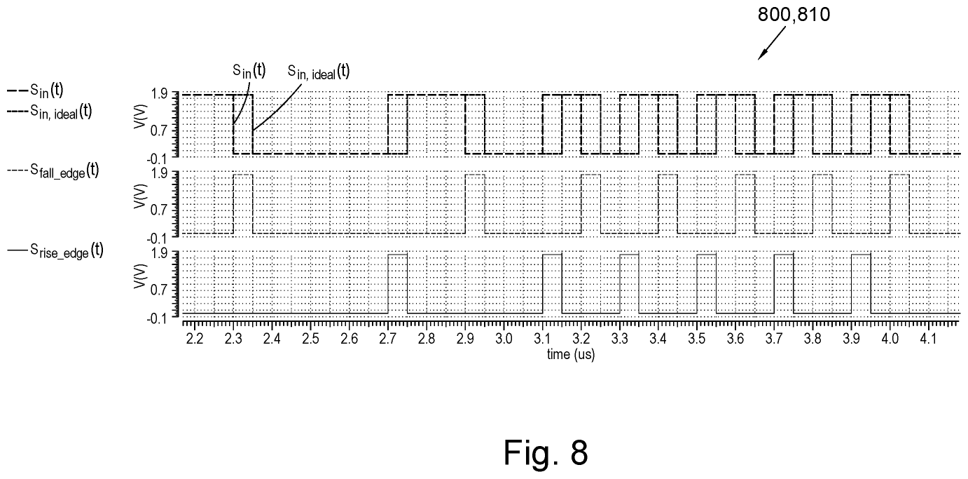

FIG. 8 shows example transient responses 800 of the rising edge detection circuit 700 during operation. As shown in FIG. 8, the signal pulses of the rising edge detection signal s_{rise_edge}(t) begin at the same or substantially the same time as the rising edges of the input signal sᵢₙ(t). Further, each of the signal pulses of the rising edge detection signal s_{rise_edge}(t) are the same or substantially the same width regardless of the pulse frequency (e.g., corresponding to the delay introduced by the delay rising edge circuit 404).

As another example, FIG. 7B shows a falling edge detection circuit 710 including a delay falling edge circuit 406. The falling edge detection circuit 710 can be used to detect falling edges of an input signal sᵢₙ(t) (e.g., portions of the input signal sᵢₙ (t) that transition from a high voltage, such as a rail voltage, to a low voltage, such as ground), and generate a signal pulse upon the occurrence of the falling edge. The falling rising edge circuit 406 can be similar to the delay falling edge circuit 406 shown and described with respect to FIG. 4.

In an example operation of the falling edge detection circuit 710, the output of the delay falling edge circuit 406 (i.e., latch reset signal sᵣₑₛ′(t)) is input into an AND gate 712. Further, an inverted version of the input signal sᵢₙ(t) (e.g., the input signal after it passes through the inverter 412 is also input into the AND gate 712. When both the latch reset signal sᵣₑₛ′(t) and the inverted version of the input signal sᵢₙ(t) are at a high voltage, the AND gate 712 outputs a high voltage as a falling edge detection signal s_{fall_edge}(t). Otherwise, the AND gate 712 outputs a low voltage as the falling edge detection signal s_{fall_edge}(t).

FIG. 8 shows example transient responses 810 of the falling edge detection circuit 710 during operation. As shown in FIG. 8, the signal pulses of the falling edge detection signal s_{fall_edge} begin at the same or substantially the same time as the falling edges of the input signal sᵢₙ(t). Further, each of the signal pulses of the falling edge detection signal s_{fall_edge} are the same or substantially the same width regardless of pulse frequency (e.g., corresponding to the delay introduced by the delay falling edge circuit 406).

### Example Systems

Some implementations of the subject matter and operations described in this specification can be implemented in digital electronic circuitry, or in computer software, firmware, or hardware, including the structures disclosed in this specification and their structural equivalents, or in combinations of one or more of them. For example, in some implementations, one or more components of the system 100, the filter module 106, the filter module 400, the rising edge detection circuit 700, and/or the falling edge detection circuit 710 can be implemented using digital electronic circuitry, or in computer software, firmware, or hardware, or in combinations of one or more of them. In another example, the process 600 shown in FIG. 6 can be implemented using digital electronic circuitry, or in computer software, firmware, or hardware, or in combinations of one or more of them.

Some implementations described in this specification can be implemented as one or more groups or modules of digital electronic circuitry, computer software, firmware, or hardware, or in combinations of one or more of them. Although different modules can be used, each module need not be distinct, and multiple modules can be implemented on the same digital electronic circuitry, computer software, firmware, or hardware, or combination thereof.

Some implementations described in this specification can be implemented as one or more computer programs, i.e., one or more modules of computer program instructions, encoded on computer storage medium for execution by, or to control the operation of, data processing apparatus. A computer storage medium can be, or can be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially generated propagated signal. The computer storage medium can also be, or be included in, one or more separate physical components or media (e.g., multiple CDs, disks, or other storage devices).

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

Some of the processes and logic flows described in this specification can be performed by one or more programmable processors executing one or more computer programs to perform actions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and processors of any kind of digital computer. Generally, a processor will receive instructions and data from a read only memory or a random access memory or both. A computer includes a processor for performing actions in accordance with instructions and one or more memory devices for storing instructions and data. A computer may also include, or be operatively coupled to receive data from or transfer data to, or both, one or more mass storage devices for storing data, e.g., magnetic, magneto optical disks, or optical disks. However, a computer need not have such devices. Devices suitable for storing computer program instructions and data include all forms of non-volatile memory, media and memory devices, including by way of example semiconductor memory devices (e.g., EPROM, EEPROM, flash memory devices, and others), magnetic disks (e.g., internal hard disks, removable disks, and others), magneto optical disks, and CD-ROM and DVD-ROM disks. The processor and the memory can be supplemented by, or incorporated in, special purpose logic circuitry.

To provide for interaction with a user, operations can be implemented on a computer having a display device (e.g., a monitor, or another type of display device) for displaying information to the user and a keyboard and a pointing device (e.g., a mouse, a trackball, a tablet, a touch sensitive screen, or another type of pointing device) by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending webpages to a web browser on a user's client device in response to requests received from the web browser.

A computer system may include a single computing device, or multiple computers that operate in proximity or generally remote from each other and typically interact through a communication network. Examples of communication networks include a local area network (“LAN”) and a wide area network (“WAN”), an inter-network (e.g., the Internet), a network comprising a satellite link, and peer-to-peer networks (e.g., ad hoc peer-to-peer networks). A relationship of client and server may arise by virtue of computer programs running on the respective computers and having a client-server relationship to each other.

While this specification contains many details, these should not be construed as limitations on the scope of what may be claimed, but rather as descriptions of features specific to particular examples. Certain features that are described in this specification in the context of separate implementations can also be combined. Conversely, various features that are described in the context of a single implementation can also be implemented in multiple embodiments separately or in any suitable sub-combination.

A number of embodiments have been described. Nevertheless, various modifications may be made without departing from the spirit and scope of the invention. Accordingly, other implementations are within the scope of the claims.

1-40. (canceled)

41. A system comprising:
an input terminal operable to receive an input signal having one or more first pulses;
a first delay circuit and a second delay circuit electrically coupled to the input terminal in parallel with one another,
wherein the first delay circuit is operable to generate a first delay signal based on the input signal, the first delay signal having one or more second pulses, wherein each second pulse comprises a respective falling edge that is delayed in time with respect to a corresponding falling edge of the one or more first pulses,
wherein the second delay circuit is operable to generate a second delay signal based on the input signal, the second delay signal having one or more third pulses, wherein each third pulse comprises a respective falling edge that is delayed in time with respect to a corresponding rising edge of the one or more first pulses; and
a latch circuit electrically coupled to the first delay circuit and the second delay circuit, wherein the latch circuit is operable to generate a latch signal based on the first delay signal and based on the second delay signal.

42. The system of claim 41, wherein the first delay circuit comprises a first filter circuit, a first trigger circuit, and a first switch,
wherein the first switch is operable to toggle closed during rising edges of the one or more first pulses of the input signal, and toggle open during falling edges of the one or more first pulses of the input signal.

43. The system of claim 42, wherein when the first switch is closed, the first switch applies a ground voltage to an input of the first trigger circuit, and
wherein when the second switch is open, a first inverted filtered version of the input signal is applied to the input of first trigger circuit.

44. The system of claim 43, wherein the first trigger circuit comprises a Schmitt trigger inverter circuit.

45. The system of claim 44, wherein the first trigger circuit is operable to output, as the first delay signal, a first upper value upon the first switch applying the ground voltage to the input of the first trigger circuit.

46. The system of claim 45, wherein the first trigger circuit is operable to output, as the first delay signal, a first lower value upon the first inverted filtered version of the input signal increasing above a first threshold value.

47. The system of claim 41, wherein the second delay circuit comprises a second filter circuit, a second trigger circuit, and a second switch,
wherein the second switch is operable to toggle closed during falling edges of the one or more first pulses of the input signal, and toggle open during rising edges of the one or more first pulses of the input signal.

48. The system of claim 47, wherein when the second switch is closed, the first switch applies a rail voltage to an input of the first trigger circuit, and
wherein when the second switch is open, a second inverted filtered version of the input signal is applied to the input of second trigger circuit.

49. The system of claim 48, wherein the second trigger circuit comprises a Schmitt trigger circuit.

50. The system of claim 49, wherein the second trigger circuit is operable to output, as the second delay signal, a second upper value upon the second switch applying the rail voltage to the input of the second trigger circuit; optionally
wherein the second trigger circuit is operable to output, as the second delay signal, a second lower value upon the second inverted filtered version of the input signal decreasing below a second threshold value.

51. The system of claim 41, wherein the latch circuit comprises an S-R latch circuit; optionally
wherein the latch circuit is operable to:
output, as the latch signal, a third upper value upon the second delay signal decreasing below a third threshold value concurrent to the first delay signal being greater than the third threshold value, and
output, as the latch signal, a third lower value upon the first delay signal decreasing below the third threshold value concurrent to the second delay signal being greater than the third threshold value.

52. The system of claim 41, wherein the input signal comprises a first signal component and a second signal component, and wherein the latch signal comprises the first signal component without the second signal component.

53. The system of claim 52, wherein the first signal component has a first frequency, wherein the second signal component has a second frequency higher than the first frequency; optionally
wherein the first frequency is 1 MHz, and wherein the second frequency is 12.5 MHz.

54. The system of claim 52, wherein the first signal component comprises one or more first portions consistent with a first communications protocol, and wherein the second signal component comprises one or more second portions consistent with a second communications protocol different from the first communications protocol; optionally wherein the first communications protocol is the Inter-Integrated Circuit (I2C) interface standard, and wherein the second communications protocol is the Mobile Industry Processor Interface (MIPI) I3C interface standard.

55. The system of claim 41, further comprising a first electrical component and a second electrical component,
wherein the first electrical component is electrically coupled to the input terminal and is operable to provide the input signal to the input terminal, and
wherein the second electrical component is electrically coupled to the latch circuit and is operable to receive the latch signal from the latch circuit.

56. The system of claim 55, wherein the first electrical component comprises a sensor, and wherein the input signal is indicative of a measurement obtained by the sensor; and/or
wherein the first electrical component comprises a communications device, and wherein the input signal comprises a communications signal generated by the communications device; and/or
wherein the second electrical component is operable to perform one or more signal processing steps based on the latch signal.

57. A method comprising:
receiving an input signal having one or more first pulses;
generating a first delay signal based on the input signal, the first delay signal having one or more second pulses, wherein each second pulse comprises a respective falling edge that is delayed in time with respect to a corresponding falling edge of the one or more first pulses;
generating a second delay signal based on the input signal, the second delay signal having one or more third pulses, wherein each third pulse comprises a respective falling edge that delayed in time with respect to a corresponding rising edge of the one or more first pulses; and
generating, by a latch circuit, a latch signal based on the first delay signal and based on the second delay signal.

58. The method of claim 57, wherein generating the first delay signal comprises:
applying a ground voltage to an input of a first trigger circuit when the input signal is greater than a first switch value, and
applying a first inverted filtered version of the input signal to the input of first trigger circuit when the input signal is less than the first switch value.

59. The method of claim 58, wherein generating the second delay signal comprises:
applying a rail voltage to an input of a second trigger circuit when the input signal is less than a second switch value, and
applying a second inverted filtered version of the input signal to the input of second trigger circuit when the input signal is greater than the second switch value.

60. A delay circuit comprising:
an input terminal; and
an output terminal,
wherein the delay circuit is operable to:
receive an input signal at the input terminal, the input signal having one or more first pulses,
generate a delay signal based on the input signal, the delay signal having one or more second pulses, wherein each second pulse comprises a respective falling edge that is delayed in time with respect to a corresponding rising edge of the one or more first pulses and a respective rising edge that is concurrent in time with a corresponding falling edge of the one or more first pulses, and
output the delay signal at the output terminal.
